(19) United States
(12) Patent Application Publication
(10) Pub. No.: US 2020/0095468 A1
(43) Pub. Date: Mar. 26, 2020

(54) TUNGSTEN DISSOLUTION INHIBITOR, AND POLISHING COMPOSITION AND COMPOSITION FOR SURFACE TREATMENT USING THE SAME

(71) Applicant: FUJIMI INCORPORATED, Kiyosu-shi (JP)

(72) Inventors: Ayano YAMAZAKI, Kiyosu-shi (JP); Tsutomu YOSHINO, Kiyosu-shi (JP); Shogo ONISHI, Kiyosu-shi (JP)

(73) Assignee: FUJIMI INCORPORATED, Kiyosu-shi (JP)

(21) Appl. No.: 16/579,395

(22) Filed: Sep. 23, 2019

(30) Foreign Application Priority Data
Sep. 25, 2018 (JP) 2018-178726

(51) Int. Cl. C09G 1/02; H01L 21/321

(52) U.S. Cl. CPC C09G 1/02; H01L 21/3212

(57) ABSTRACT

The present invention is to provide means which can inhibit dissolution of tungsten-containing material by bringing a specific compound into contact with the tungsten-containing material. The present invention relates to a tungsten dissolution inhibitor which contains a sulfonic acid compound or a salt thereof containing a nitrogen atom and having a molecular weight of less than 1,000.

### CROSS-REFERENCE TO RELATED APPLICATION

The present application is based on the Japanese patent application No. 2018-178726 filed on Sep. 25, 2018, and a disclosed content thereof is incorporated herein as a whole by reference.

### BACKGROUND

### 1. Technical Field

The present invention relates to a tungsten dissolution inhibitor, and a polishing composition and a composition for surface treatment using the same. In addition, the present invention also relates to a method of producing a polishing composition and a composition for surface treatment, a surface treatment method and a polishing method, and a method of manufacturing a semiconductor substrate.

### 2. Description of Related Arts

In recent years, according to the trend of multilayer interconnections on a surface of a semiconductor substrate, a so-called chemical mechanical polishing (CMP) technology has been used to physically polish and planarize a semiconductor substrate at the time of manufacturing a device. The CMP is a method of planarizing a surface of an object to be polished (polished object) such as a semiconductor substrate using a polishing composition (slurry) containing abrasive grains such as silica, alumina, and ceria, anticorrosives, surfactants and the like, and the object to be polished (polished object) is a wiring, a plug or the like which is made of silicon, polysilicon, silicon oxide, silicon nitride, metal or the like.

As the polishing composition used for such CMP, JP 2013-42131 A (corresponding to Specification of US Patent Application Publication No. 2013/015437) discloses an oxidizing agent-free polishing composition capable of inhibiting a recess (phenomenon that tungsten is polished excessively) of a tungsten plug.

Further, a large amount of impurities (residues, foreign matters) remain on the object to be polished after the polishing process. Examples of the impurities include organic substances such as abrasive grains, metals, anticorrosives, surfactants derived from the polishing composition used in the CMP, silicon-containing materials as an object to be polished, silicon-containing materials or metals generated by polishing a metal wiring, a plug or the like, and furthermore organic substances such as pad scraps generated from various pads or the like, and the like. Contamination of a surface of the polished object to be polished may cause defects of products using the polished object to be polished, and may be a cause of reduction in performance or reliability of the products. For example, if the surface of the semiconductor substrate is contaminated by these impurities, electrical properties of semiconductor may be adversely affected, which causes the reduction in reliability of the device. Therefore, it is preferable to remove these impurities from the surface of the polished object to be polished by introducing a cleaning process after the polishing process.

As a cleaning composition used for such cleaning, JP 2011-159658 A discloses a cleaning composition which contains an organic amine, a tertiary ammonium hydroxide, a chelating agent, and water and has having a pH of 7.0 to 14.0. The document discloses that this cleaning composition can well remove particle residues and metal residues derived from abrasive particles while inhibiting the corrosion of tungsten.

### SUMMARY

However, there is a problem that the effect of inhibiting the corrosion (dissolution) of a tungsten-containing layer is not sufficient in the case of polishing the object to be polished having the tungsten-containing layer with the polishing composition disclosed in JP 2013-42131 A (corresponding to Specification of US Patent Application Publication No. 2013/015437) or cleaning the surface of the polished object to be polished having the tungsten-containing layer with the cleaning composition disclosed in JP 2011-159658 A. Such corrosion is a cause of the defects of products, the reduction in performance and reliability of the products, and the like.

Therefore, an object of the present invention is to provide means which can inhibit dissolution of tungsten-containing material by bringing a specific compound into contact with the tungsten-containing material.

An aspect for solving the above problems is a tungsten dissolution inhibitor which contains a sulfonic acid compound or a salt thereof containing nitrogen atoms and having a molecular weight of less than 1000.

### DETAILED DESCRIPTION

Embodiments of the present invention will be described below. Note that the present invention is not limited to the following embodiments. In addition, unless otherwise indicated, a measurement of an operation and physical properties and the like is conducted under conditions of room temperature (range of 20° C. or higher and 25° C. or lower)/relative humidity of 40% RH or more and 50% RH or less.

In addition, “(meth)acrylate” is a general term for acrylate and methacrylate. Similarly, the compound and the like which contain (meth), such as (meth)acrylic acid are a generic term of compounds which have “meth” in a name, and compounds which do not have “meth” in a name.

<Tungsten Dissolution Inhibitor>

An aspect of the present invention is a tungsten dissolution inhibitor which contains a sulfonic acid compound or a salt thereof containing nitrogen atoms and having a molecular weight of less than 1,000. According to an aspect of the present invention, there is provided means which can inhibit dissolution of tungsten-containing material by bringing a specific compound into contact with the tungsten-containing material.

The present inventors presume mechanism capable of solving the above problems as follows.

The dissolution of the tungsten-containing material is attributed to the fact that the material forms a hydrate (WXOYA-) with water which is contained in the polishing composition or in the composition for surface treatment to be easily dissolved. Since the tungsten dissolution inhibitor according to an aspect of the present invention contains a sulfonic acid compound or a salt thereof (herein, simply referred to as “nitrogen-containing sulfonic acid compound”) which has nitrogen atoms included in a molecule thereof and has a molecular weight of less than 1,000, the nitrogen-containing sulfonic acid compound is adsorbed into the tungsten-containing material to protect the surface of the material. Specifically, the nitrogen-containing sulfonic acid compound is coordinated to a surface of the tungsten-containing material by the nitrogen atoms included in the molecule thereof. By the stable coordination of these nitrogen atoms, the tungsten-containing material together with a sulfonic acid group (—SO₃H) or a salt thereof forms an insoluble complex on a surface thereof. As a result, the hydration of the tungsten-containing material is inhibited, and the nitrogen-containing sulfonic acid compound functions as an inhibitor (dissolution inhibitor) which inhibits the dissolution of the tungsten-containing material.

Note that the above mechanism is based on the presumption, and the right or wrong of the presumption does not affect the technical scope of the present invention.

[Tungsten-Containing Material]

In the present specification, “containing tungsten” represents containing tungsten element, and the tungsten element may be contained in any form of tungsten alone, alloys containing tungsten, or compounds containing tungsten. Among these, tungsten alone or an alloy mainly made of tungsten, that is, an alloy (tungsten alloy) having the largest proportion of a mass of tungsten in the metal constituting the alloy is preferable, and the tungsten alone is more preferable.

In addition, the tungsten-containing material may be in any form as long as the surface to be treated contains tungsten, but a tungsten-containing layer which is a planar member having a single layer or a laminated structure is preferable, a substrate containing the layer is more preferable, and a semiconductor substrate containing the layer is still more preferable.

Preferred examples of the tungsten-containing material include a substrate including a layer formed only of a constituent part containing tungsten, a substrate including a layer formed only of a constituent part containing tungsten and other layers (for example, a support layer and other functional layers), a substrate including a layer formed of a constituent part containing tungsten and an a constituent part formed of other compositions not containing tungsten, a substrate including a layer formed of a constituent part containing tungsten and a constituent part formed of other compositions not containing tungsten, and other layers (for example, a support layer or other functional layers), and the like.

When the surface to be treated is a layer including a constituent part containing tungsten and a constituent part containing other compositions not containing tungsten, the constituent part containing other compositions is not particularly limited, but is a constituent part of materials containing silicon or a constituent part made of metals other than tungsten or an alloy containing the same.

The material containing silicon is not particularly limited, but examples thereof include silicon nitride (SiN), silicon carbonitride (SiCN), and the like. A material containing a silicon-oxygen bond is not particularly limited, but examples thereof include silicon oxide, black diamond (BD: SiOCH), FSG (fluorosilicate glass), HSQ (hydrogen silsesquioxane), CYCLOTENE, SiLK, MSQ (methyl silsesquioxane), and the like. The object to be polished having a silicon-silicon bond is not particularly limited, but examples thereof include polysilicon, amorphous silicon, single crystal silicon, n-type doped single crystal silicon, p-type doped single crystal silicon, Si-based alloys such as SiGe, and the like.

Examples of the portion made of silicon oxide include TEOS (tetraethyl orthosilicate) type silicon oxide surface (hereinafter, also simply referred to as “TEOS”) generated using tetraethyl orthosilicate as a precursor, an HDP (high density plasma) film, a USG (undoped silicate glass) film, a PSG (phosphorus silicate glass) film, a BPSG (boron-phospho silicate glass) film, an RTO (rapid thermal oxidation) film, and the like.

A material which constitutes the constituent part made of metals other than tungsten or an alloy containing the same is not particularly limited, but examples thereof include copper, aluminum, hafnium, cobalt, nickel, titanium, alloys thereof, and the like.

[Sulfonic Acid Compound or Salt Thereof Containing Nitrogen Atom]

The tungsten dissolution inhibitor according to an embodiment of the present invention contains a sulfonic acid compound or a salt thereof (nitrogen-containing sulfonic acid compound) containing a nitrogen atom and having a molecular weight of less than 1,000. As described above, the nitrogen-containing sulfonic acid compound contributes to the inhibition of the dissolution of the tungsten-containing material. That is, the nitrogen-containing sulfonic acid compound functions as a dissolution inhibitor (inhibitor) which inhibits the dissolution and the like of the tungsten-containing material. In the present specification, a compound used for the purpose of imparting such a function is also referred to as a tungsten dissolution inhibitor compound.

In addition, the nitrogen-containing sulfonic acid compound can also contribute to the inhibition of an increase (increase in a value of average surface roughness Ra) in surface roughness of the tungsten-containing material. The increase in surface roughness of the tungsten-containing material is believed to be due to a corrosion of grain boundaries. On the other hand, as described above, the effect of the nitrogen-containing sulfonic acid compound as an inhibitor inhibits the dissolution of the tungsten-containing material, and simultaneously inhibits the dissolution of the grain boundaries of the tungsten-containing material. As a result, the smoothness of the surface of the tungsten-containing material can be well maintained.

The nitrogen-containing sulfonic acid compound is not particularly limited as long as it is a compound having a nitrogen atom and one or more sulfonic acid (salt) groups. In the present specification, the sulfonic acid (salt) group represents a sulfonic acid group (—SO₃H) or a group (sulfonic acid group, —SO₃M¹, with M¹ being an organic or inorganic cation) of a salt thereof. That is, in the nitrogen-containing sulfonic acid compound, at least some or all of the sulfonic acid groups may be in a form of a salt.

The number of nitrogen atoms in one molecule of the nitrogen-containing sulfonic acid compound is not particularly limited as long as it is 1 or more, but is preferably 2 or more from the viewpoint of easy coordination to the tungsten-containing material or from the viewpoint of the dissolution inhibiting effect of the tungsten-containing material. On the other hand, the number of nitrogen atoms is not particularly limited, but is preferably 8 or less, more preferably 6 or less, still more preferably 4 or less, and particularly preferably 3 or less from the viewpoint of easily removing the nitrogen-containing sulfonic acid compound itself from the tungsten-containing material after the treatment.

The number of sulfonic acid (salt) groups of the nitrogen-containing sulfonic acid compound is not particularly limited as long as it is 1 or more, but is preferably 2 or more, and 4 or more from the viewpoint of easily forming an insoluble complex. On the other hand, the number of sulfonic acid (salt) groups of the nitrogen-containing sulfonic acid compound is preferably 10 or less, more preferably 8 or less, still more preferably 6 or less, and particularly preferably 5 or less from the viewpoint of easily removing the nitrogen-containing sulfonic acid compound after the treatment.

The molecular weight of the nitrogen-containing sulfonic acid compound is less than 1,000. When the molecular weight is 1,000 or more, an adsorption rate of the nitrogen-containing sulfonic acid compound is reduced by increasing the molecular weight to delay the dissolution inhibition rate of tungsten, so the tungsten inhibiting effect cannot be sufficiently obtained. In addition, the molecular weight of the nitrogen-containing sulfonic acid compound is not particularly limited, but is preferably 900 or less, more preferably 800 or less, still more preferably 700 or less, and particularly preferably 600 or less from the viewpoint of easily removing the nitrogen-containing sulfonic acid compound after the treatment. On the other hand, the lower limit of the molecular weight of the nitrogen-containing sulfonic acid compound is not particularly limited, but is preferably 120 or more, more preferably 200 or more, still more preferably 250 or more, even more preferably 300 or more, particularly preferably 350 or more, and most preferably 400 or more from the viewpoint of the dissolution inhibiting effect of the tungsten-containing material. The molecular weight of the nitrogen-containing sulfonic acid compound can be evaluated by mass spectrometry (MS) such as gas chromatography-mass spectrometry (GC-MS) and HPLC-tandem quadrupole mass spectrometry, high performance liquid chromatography (HPLC) and the like. When the molecular structure is clear, it can be calculated from the sum of atomic weights.

Here, when the nitrogen-containing sulfonic acid compound is in the state of a salt (partially containing a salt), the molecular weight represents the molecular weight in the state of a salt.

The nitrogen-containing sulfonic acid compound is preferably a compound represented by the following formula (1):

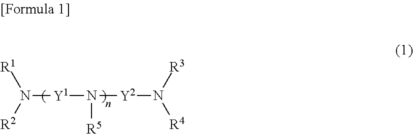

In the formula (1),

Y¹ and Y² each independently represent a linear or branched alkylene group having 1 or more and 5 or less carbon atoms,

n is an integer of 0 or more and 4 or less,

R¹ to R⁵ each independently represent a hydrogen atom, a sulfonic acid (salt) group or a substituted or unsubstituted linear or branched alkyl group having 1 or more and 5 or less carbon atoms, and in this case, at least one of R¹ to R⁵ is a sulfonic acid (salt) group or an alkyl group substituted with the sulfonic acid (salt) group.

In the above formula (1), the linear or branched alkylene group having 1 or more and 5 or less carbon atoms as Y¹ and Y² is not particularly limited, and examples thereof include a methylene group, an ethylene group, a trimethylene group, a tetramethylene group, propylene group, and the like. Among those, the linear or branched alkylene group having 1 or more and 4 or less carbon atoms is preferable, and the linear or branched alkylene group having 1 or more and 3 or less carbon atoms is more preferable. Furthermore, from the viewpoint of the dissolution inhibiting effect of tungsten or the availability, an alkylene group having 1 or 2 carbon atoms, that is, a methylene group or an ethylene group is more preferable, and an ethylene group is particularly preferable.

In the above formula (1), n represents the number of (—Y¹—N(R⁵)—) and is preferably an integer of 0 or more and 4 or less. n is more preferably an integer of 0 or more and 2 or less, still more preferably 1 or 2, and particularly preferably 1, from the viewpoint of the improvement in the dissolution inhibiting effect of tungsten or the availability. When n is 2 or more, n (—Y¹—N(R⁵)—) may be the same or different, but is preferably the same.

In the above formula (1), the substituted or unsubstituted linear or branched alkyl group having 1 or more and 5 or less carbon atoms as R¹ to R⁵ is not particularly limited, and examples thereof include a methyl group, an ethyl group, a propyl group, an isopropyl group, a butyl group, an isobutyl group, a sec-butyl group, a tert-butyl group and the like. Among those, the substituted or unsubstituted linear or branched alkyl group having 1 or more and 4 or less carbon atoms is preferable, and the substituted or unsubstituted linear or branched alkyl group having 1 or more and 3 or less carbon atoms is more preferable. Furthermore, from the viewpoint of the dissolution inhibiting effect or the availability of tungsten, a methyl group and an ethyl group are more preferable, and the methyl group is particularly preferable.

Here, the “substituted or unsubstituted” as to the alkyl group means that one or more hydrogen atoms of the alkyl group may be substituted or not with another substituent. Here, the substituent is not particularly limited, but examples thereof include a fluorine atom (F); a chlorine atom (Cl); a bromine atom (Br); an iodine atom (I); a phosphoric acid group (—PO₃H₂) or a salt thereof; a phosphoric acid group (—OPO₃H₂) or a salt thereof; a sulfonic acid group (—SO₃H) or a group of a salt thereof; an amino group (—NH₂, —NHR or —NRR′, in which R and R′ each independently represent a hydrocarbon group, preferably a linear or branched alkylene group having 1 or more and 5 or less carbon atoms) or a group of a salt thereof; a thiol group (—SH); a cyano group (—CN); a nitro group (—NO₂); a hydroxy group (—OH); a linear or branched alkoxy group having 1 or more and 10 or less carbon atoms (for example, a methoxy group, an ethoxy group, a propoxy group, an isopropoxy group, a butoxy group, a pentyloxy group, a hexyloxy group, a 2-ethylhexyloxy group, an octyloxy group, a dodecyloxy group and the like); an aryl group having 6 or more and 30 or less carbon atoms (for example, a phenyl group, a biphenyl group, a 1-naphthyl group, and a 2-naphthyl group); a cycloalkyl group having 3 or more and 20 or less carbon atoms (for example, a cyclopropyl group, a cyclobutyl group, a cyclopentyl group, a cyclohexyl group, and a cycloheptyl group) and the like.

In the above formula (1), at least one of R¹ to R⁵ is a sulfonic acid (salt) group or an alkyl group substituted with the sulfonic acid (salt) group. The “alkyl group substituted with the sulfonic acid (salt) group” is the linear or branched alkyl group having 1 or more and 5 or less carbon atoms which is substituted with one or more sulfonic acid (salt) group, and examples thereof include a sulfo-methyl group, a sulfo-ethyl group, a sulfo-n-propyl group, a sulfo-isopropyl group, a sulfo-n-butyl group, a sulfo-isobutyl group, a sulfo-sec-butyl group, a sulfo-tert-butyl group, a group of a salt thereof, and the like. Among those, the linear or branched alkyl group having 1 or more and 4 or less carbon atoms substituted with one sulfonic acid (salt) group is preferable, and the linear or branched alkyl group of 1 or more and 3 or less carbon atoms substituted with one sulfonic acid group is more preferable. Furthermore, from the viewpoint of the dissolution inhibiting effect or the availability of tungsten, the sulfo-methyl group, the sulfo-ethyl group or the group of the salt thereof is preferable, and the sulfo-methyl group or the group of the salt thereof is particularly preferable.

In the above formula (1), in R¹ to R⁵, the number of the sulfonic acid (salt) group or the alkyl group substituted with the sulfonic acid (salt) group is not particularly limited as long as it is one or more, but preferably 2 or more and more preferably 4 or more from the viewpoint of the dissolution inhibiting effect of the tungsten-containing material. Furthermore, from the viewpoint of the dissolution inhibiting effect of tungsten, all of R¹ to R⁴ are more preferably the sulfonic acid (salt) group or the linear or branched alkyl group having 1 or more and 5 or less carbon atoms substituted with the sulfonic acid (salt) group, all of R¹ to R⁴ and n R⁵s (n R5 groups) are particularly preferably the sulfonic acid (salt) group or the linear or branched alkyl group having 1 or more and 5 or less carbon atoms substituted with the sulfonic acid (salt) group, and all of R¹ to R⁴ and n R⁵s are most preferably the sulfonic acid (salt) group.

Preferred examples of the nitrogen-containing sulfonic acid compound include N,N-bis (2-hydroxyethyl)-2-amino ethane sulfonic acid, 2-amino-1-naphthalene sulfonic acid, 2-amino ethane sulfonic acid (amino ethyl sulfonic acid), ethylene diamine tetraethylene sulfonic acid, ethylene diamine tetramethylene sulfonic acid (ethylene diamine tetra (methylene sulfonic acid)), ethylene diamine tetrasulfonic acid, diethylene triamine pentaethylene sulfonic acid, diethylene triamine pentamethylene sulfonic acid (diethylene triamine penta (methylene sulfonic acid)), diethylene triamine pentasulfonic acid, triethylene tetramine hexaethylene sulfonic acid, triethylene tetramine hexamethylene sulfonic acid, triethylene tetramine hexasulfonic acid, propane diamine tetraethylene sulfonic acid, propane diamine tetramethylene sulfonic acid and propane diamine tetrasulfonic acid, and ammonium salts, potassium salts, sodium salts, and lithium salts thereof, and the like. Considering the dissolution inhibiting effect of the tungsten, the availability, or the like, among those, ethylene diamine tetraethylene sulfonic acid, ethylene diamine tetramethylene sulfonic acid (ethylene diamine tetra (methylene sulfonic acid)), ethylene diamine tetrasulfonic acid, diethylene triamine pentaethylene sulfonic acid, diethylene triamine pentamethylene sulfonic acid (diethylene triamine penta (methylene sulfonic acid)), diethylene triamine pentasulfonic acid, triethylene tetramine hexaethylene sulfonic acid, triethylene tetramine hexamethylene sulfonic acid, triethylene tetramine hexasulfonic acid, propane diamine tetraethylene sulfonic acid, and propane diamine tetramethylene sulfonic acid, propane diamine tetrasulfonic acid and ammonium salts, potassium salts, sodium salts, and lithium salts thereof are more preferable, ethylene diamine tetrasulfonic acid, diethylene triamine pentasulfonic acid, and triethylene tetramine hexasulfonic acid, and ammonium salts, potassium salts, sodium salts, and lithium salts thereof are furthermore preferable, diethylene triamine pentasulfonic acid, and triethylene tetramine hexasulfonic acid, and ammonium salts, potassium salts, sodium salts, and lithium salts thereof are still more preferable, and diethylene triamine pentasulfonic acid and ammonium salts, potassium salts, sodium salts and lithium salts thereof are particularly preferable. That is, the nitrogen-containing sulfonic acid compound according to an embodiment of the present invention preferably contains at least one selected from the group consisting of the nitrogen-containing sulfonic acid compounds exemplified above.

The nitrogen-containing sulfonic acid compounds may be used alone or in combination of two or more.

The tungsten dissolution inhibitor may be a composition (herein also simply referred to as a “tungsten dissolution inhibitor composition”) containing a nitrogen-containing sulfonic acid compound and components other than the nitrogen-containing sulfonic acid compound.

When the tungsten dissolution inhibitor is a tungsten dissolution inhibitor composition, the content of the nitrogen-containing sulfonic acid compound is not particularly limited, but is preferably 0.01% by mass or more, more preferably 0.1% by mass or more, still more preferably 0.2% by mass or more, and particularly preferably 0.5% by mass or more based on the total mass of the tungsten dissolution inhibitor composition. Within this range, the dissolution inhibiting effect of the tungsten-containing material is enhanced. In addition, the content of the nitrogen-containing sulfonic acid compound is preferably less than 100% by mass, more preferably 10% by mass or less, still more preferably 5% by mass or less, and particularly preferably 2% by mass or less based on the total mass of the tungsten dissolution inhibitor composition. Within this range, the ease of removal of the nitrogen-containing sulfonic acid compound after the treatment is enhanced.

Hereinafter, each component other than the nitrogen-containing sulfonic acid compound which may be contained in the tungsten dissolution inhibitor composition will be described.

[Dispersing Medium]

The tungsten dissolution inhibitor (tungsten dissolution inhibitor composition) according to an embodiment of the present invention preferably further includes a dispersing medium (solvent). The dispersing medium has a function of dispersing or dissolving each component.

The dispersing mediums may be used alone or in combination of two or more.

The dispersing medium is not particularly limited, but preferably contains water. The content of water in the dispersing medium is not particularly limited, but is preferably 50% by mass or more and more preferably 90% by mass or more based on the total mass of the dispersing medium, and it is more preferably that the dispersing medium contains only water. Water is preferably water containing as little impurity as possible, from the viewpoint of preventing the contamination of the object to be polished or the polished object to be polished, or preventing the action of other components from being inhibited. For example, water having a total content of transition metal ions of 100 ppb or less is preferable. Here, purity of water can be increased by operations such as removal of impurity ions using an ion exchange resin, removal of foreign matters by a filter, and distillation. Specifically, examples of the water preferably include deionized water (ion-exchanged water), pure water, ultrapure water, distilled water or the like.

In addition, the dispersing medium may be an organic solvent or a mixed solvent of water and the organic solvent, as long as it can enhance dispersibility or solubility of each component. The organic solvent is not particularly limited, and the known organic solvent can be used. As the mixed solvent of the water and the organic solvent, acetone, acetonitrile, ethanol, methanol, isopropanol, glycerin, ethylene glycol, propylene glycol or the like which is the organic solvent mixed with the water is preferably used. When the organic solvent is used, the water and the organic solvent may be mixed, each component may be added to and dispersed or dissolved in the obtained mixed solvent, or these organic solvents may be used without being mixed with water, and each component may be dispersed or dissolved and then mixed with water. Alternatively, water may be used without being mixed with these organic solvents, and each component may be dispersed or dissolved and then mixed with these organic solvents. The organic solvents may be used alone or in combination of two or more.

[Polishing Composition]

The tungsten dissolution inhibitor (tungsten dissolution inhibitor composition) according to an embodiment of the present invention can be a polishing composition used to polish an object to be polished having a tungsten-containing layer as long as it contains a dispersing medium. That is, another aspect of the present invention relates to the polishing composition which is used for polishing the object to be polished having the tungsten-containing layer and is the tungsten dissolution inhibitor containing the dispersing medium (preferably water). In other words, the present aspect relates to the polishing composition which contains a nitrogen-containing sulfonic acid compound and the dispersing medium (preferably water) and is used for polishing the object to be polished having the tungsten-containing layer. Such a polishing composition according to the present invention is excellent in the tungsten dissolution inhibiting effect while maintaining a high polishing speed, and can further reduce the number of defects on the surface of the object to be polished after the polishing.

The polishing composition according to an embodiment of the present invention may contain components other than the nitrogen-containing sulfonic acid compound and the dispersing medium within the range in which these components do not inhibit the tungsten dissolution inhibiting effect and the effect as the polishing composition. In this case, a preferable embodiment of the present invention relates to a polishing composition as the tungsten dissolution inhibitor composition which is used for polishing the object to be polished having the tungsten-containing layer and contains an abrasive grain described below and the dispersing medium (preferably water). In other words, the present embodiment relates to the polishing composition which contains the nitrogen-containing sulfonic acid compound, the dispersing medium (preferably water), and the abrasive grain described below and is used for polishing the object to be polished having the tungsten-containing layer.

[Composition for Surface Treatment]

The tungsten dissolution inhibitor (tungsten dissolution inhibitor composition) according to an embodiment of the present invention can be a composition for surface treatment used to treat a surface of a polished object to be polished having a tungsten-containing layer as long as it contains a dispersing medium. That is, another aspect of the present invention relates to the composition for surface treatment which is used for treating the surface of the polished object to be polished having the tungsten-containing layer and is the tungsten dissolution inhibitor containing the dispersing medium (preferably water). In other words, the present aspect relates to the composition for surface treatment which contains a nitrogen-containing sulfonic acid compound and the dispersing medium (preferably water) and is used for treating the surface of the polished object to be polished having the tungsten-containing layer. Here, the surface treatment is preferably a treatment for reducing the number of residues on the surface of a polished object to be polished, such as a cleaning treatment or a rinse polishing treatment described later. Such composition for surface treatment according to the present invention is excellent in the tungsten dissolution inhibiting effect and can further reduce the number of defects on the surface of the polished object to be polished.

The tungsten dissolution inhibitor (tungsten dissolution inhibitor composition) according to the embodiment of the present invention may further contain components other than the nitrogen-containing sulfonic acid compound and the dispersing medium optionally used within the range in which the tungsten dissolution inhibiting effect is not inhibited.

Hereinafter, components other than the nitrogen-containing sulfonic acid compound and the dispersing medium that may be contained in the tungsten dissolution inhibitor (tungsten dissolution inhibitor composition) according to an embodiment of the present invention will be described.

[Anionic Polymer Dispersant]

The tungsten dissolution inhibitor (tungsten dissolution inhibitor composition) according to an embodiment of the present invention may further include a polymer compound having an anionic functional group or a group of a salt thereof and having a weight average molecular weight of 1,000 or more (herein referred to as an “anionic polymer dispersant”).

In particular, the polishing composition according to an embodiment of the present invention and the composition for surface treatment according to an embodiment of the present invention preferably further include an anionic polymer dispersant. The dispersant has a function of reducing a surface tension by surface active performance and reducing the number of defects on the surface after the treatment.

Note that in the present specification, the anionic functional group means a functional group in which a counter ion is dissociated to become an anion (to be anionized).

The present inventors presume as follows the mechanism that the anionic polymer dispersant may reduce the number of defects on the surface after the treatment.

Due to the affinity between the anionized anionic functional group and the hydrophilic residues, the anionic polymer dispersant adsorbs the anionized anionic functional group into the periphery thereof toward both the residue side and the opposite side thereof. In addition, due to the affinity between a portion (that is, a polymer chain portion of the anionic polymer dispersant) other than the anionic functional group and hydrophobic residues, the anionic polymer dispersant adsorbs the anionized anionic functional group into the periphery thereof toward the opposite side to the residues to form micelles. Therefore, the residues adsorbed on the anionic polymer dispersant are dissolved or dispersed in the polishing composition or the composition for surface treatment and thus are effectively removed. Furthermore, when the surface of the object to be polished or the object to be subjected to surface treatment is cationic, the anionic polymer dispersant adsorbs the anionized anionic functional group on the surface thereof toward both the surface side and the opposite side thereto. In addition, when the surface of the object to be polished or the object to be subjected to surface treatment is not cationic, the anionic polymer dispersant adsorbs the anionized anionic functional group on the surface thereof toward the opposite side to the surface. As a result, these surfaces become covered with the anionized anionic functional group and become hydrophilic. Then, electrostatic repulsion occurs between these surfaces and the residues adsorbed into the anionic polymer dispersant, and hydrophobic interaction is less likely to occur between some of hydrophobic residues that make adsorption of the anionic polymer dispersant less likely to occur, so adhesion of residues is suppressed.

Note that the above mechanism is based on the presumption, and the right or wrong of the presumption does not affect the technical scope of the present invention.

The anionic functional group contained in the anionic polymer dispersant or a group of a salt thereof is not particularly limited, and examples thereof include a sulfonic acid (salt) group, a sulfuric acid (salt) group, a phosphoric acid (salt) group, and a phosphonic acid (salt) group, a carboxylic acid (salt) group (carboxyl group or group of a salt thereof) and the like.

That is, examples of the anionic polymer dispersant include a polymer compound or the like having at least one functional group selected from the group consisting of a sulfonic acid (salt) group, a sulfuric acid (salt) group, a phosphoric acid (salt) group, a phosphonic acid (salt) group, and a carboxylic acid (salt) group, but among those, from the viewpoint of the reduction effect of the number of defects on the surface after treatment, a polymer compound having a sulfonic acid (salt) group, a phosphoric acid (salt) group, or a phosphonic acid (salt) group is preferable and has a polymer compound having a sulfonic acid (salt) group is particularly preferable.

Here, the anionic polymer dispersant may have a carboxylic acid (salt) group and an anionic functional group other than the carboxylic acid (salt) group or a group of a salt thereof. The ratio (%) of the number of carboxylic acid (salt) groups to the total number of anionic functional groups or group of salts thereof contained in one molecule of the anionic polymer dispersant is not particularly limited, but is preferably 50% or less, more preferably 20% or less, still more preferably 10% or less, particularly preferably 1% or less, and most preferably 0% (lower limit 0%).

The ratio of the number of carboxylic acid (salt) groups to the total number of anionic functional groups or groups of salts thereof contained in one molecule of the anionic polymer dispersant can be determined by the known method. In particular, when the anionic polymer dispersant is a (co)polymer, the ratio (%) of the carboxylic acid (salt) group to the total number of groups of anionic functional groups or groups of salts thereof contained in one molecule of the anionic polymer dispersant can be obtained by the following equation.

Ratio (%) of carboxylic acid (salt) group to total number of anionic functional groups contained in molecule=(the number of constituent units derived from monomer having carboxylic acid (salt) group/the number of constituent units derived from monomer having anionic functional group)×100 [Equation 1]

As described above, the particularly preferred anionic polymer dispersant is a polymer compound having a sulfonic acid (salt) group (herein, also simply referred to as “sulfonic acid group-containing polymer”). Here, the definition of the sulfonic acid (salt) group in the anionic polymer dispersant is the same as that described for the above-described nitrogen-containing sulfonic acid compound.

The sulfonic acid group-containing polymer is not particularly limited as long as it has a plurality of sulfonic acid (salt) groups, and the known compounds can be used. Examples of the sulfonic acid group-containing polymer include a polymer compound obtained by sulfonation of a polymer compound as a base, a polymer compound obtained by (co)polymerizing a monomer having a sulfonic acid (salt) group or the like. At least some or all of the sulfonic acid groups contained in these polymers may be in a form of a salt. Among those, sulfonic acid-modified polyvinyl alcohol (sulfonic acid group-containing polyvinyl alcohol, sulfonic acid group-containing modified polyvinyl alcohol), sulfonic acid group-containing polystyrene (sulfonic acid group-containing modified polystyrene) such as polystyrene sulfonic acid, sulfonic acid-modified polyvinyl acetate (sulfonic acid group-containing polyvinyl acetate, sulfonic acid group-containing modified polyvinyl acetate), sulfonic acid group-containing polyester (sulfonic acid group-containing modified polyester), copolymers of (meth) acrylic group-containing monomer-sulfonic acid group-containing monomers such as copolymers of (meth) acrylic acid-sulfonic acid group-containing monomers, and derivatives thereof and the like, and ammonium salts, potassium salts, sodium salts and lithium salts thereof are preferable, and sulfonic acid-modified polyvinyl alcohol, sulfonic acid group-containing polystyrene, and copolymers of (meth) acrylic group-containing monomer-sulfonic acid group-containing monomers, and ammonium salts, potassium salts, sodium salts, and lithium salts thereof are more preferable, and polystyrene sulfonic acid or ammonium salts, potassium salts, sodium salts, and lithium salt thereof are still more preferable.

The weight average molecular weight of the anionic polymer dispersant is 1,000 or more. The reason is that if the molecular weight is less than 1,000, the residues on the surface after the treatment cannot be sufficiently removed. In addition, the weight average molecular weight of the anionic polymer dispersant is not particularly limited, but is preferably 3,000 or more, and more preferably 5,000 or more. Within this range, the number of defects on the surface after the treatment is further reduced. It is presumed that the reason is that the removal performance of residues is enhanced. In addition, the weight average molecular weight of the anionic polymer dispersant is not particularly limited, but is preferably 100,000 or less, more preferably 50,000 or less, still more preferably 25,000 or less, and particularly preferably 15,000 or less. Within this range, the number of defects on the surface after the treatment is further reduced. It is presumed that the reason is that the ease of removal of the sulfonic acid group-containing polymer after the treatment is enhanced. The weight average molecular weight can be measured by gel permeation chromatography (GPC).

The anionic polymer dispersant may be either a synthetic product or a commercially available product.

Note that the anionic polymer dispersants may be used alone or in combination of two or more.

The content of the anionic polymer dispersant is not particularly limited, but is preferably 0.01% by mass or more, more preferably 0.05% by mass or more, still more preferably 0.1% by mass or more, and particularly preferably 0.25% by mass or more based on the total mass of the polishing composition or the composition for surface treatment. Within this range, the number of defects on the surface after the treatment is further reduced. It is presumed that the reason is that the removal performance of residues is enhanced. In addition, the content of the anionic polymer dispersant is preferably 5% by mass or less, more preferably 2.5% by mass or less, and still more preferably 1% by mass or less based on the total mass of the polishing composition or the composition for surface treatment. Within this range, the number of defects on the surface after the treatment is further reduced. It is presumed that the reason is that the ease of removal of the anionic polymer dispersant itself after the treatment is enhanced.

In the polishing composition according to an embodiment of the present invention and the composition for surface treatment according to an embodiment of the present invention, the content ratio of the nitrogen-containing sulfonic acid compound and the anionic polymer dispersant is not particularly limited, and from the viewpoint of enhancing the tungsten dissolution inhibiting effect, the content (part by mass) of the nitrogen-containing sulfonic acid compound to the content (part by mass) of the anionic polymer dispersant (the content (part by mass) of the nitrogen-containing sulfonic acid compound/the content of the anionic polymer dispersant (part by mass)) is preferably 0.5 or more, more preferably 1 or more, and still more preferably 1.5 or more. In addition, in the polishing composition according to an embodiment of the present invention and the composition for surface treatment according to an embodiment of the present invention, from the viewpoint of enhancing the reduction effect of the number of defects, the content ratio of the nitrogen-containing sulfonic acid compound and the anionic polymer dispersant is preferably 10 or less, more preferably 5 or less, and still more preferably 3 or less.

[Abrasive Grain]

The tungsten dissolution inhibitor (tungsten dissolution inhibitor composition) according to an embodiment of the present invention may preferably further include an abrasive grain.

In particular, the polishing composition according to an embodiment of the present invention preferably includes an abrasive grain. The abrasive grain has a function of mechanically polishing the object to be polished and enhancing a polishing speed.

The abrasive grain may be any of inorganic particles, organic particles, and organic-inorganic composite particles. Examples of the inorganic particles include particles made of metal oxides such as silica, alumina, ceria, and titania, silicon nitride particles, silicon carbide particles, boron nitride particles and the like. Specific examples of the organic particles include, for example, polymethyl methacrylate (PMMA) particles and the like. Among those, silica is preferable, fumed silica or colloidal silica is more preferable, and colloidal silica is still more preferable, from the viewpoint of ease of availability or cost.

Also, the abrasive grain may be surface modified. The surface-modified abrasive grain is preferably silica (organic acid-modified silica) having an organic acid immobilized on a surface thereof, more preferably fumed silica or colloidal silica having an organic acid immobilized on a surface thereof, and still more preferably colloidal silica having an organic acid immobilized on a surface thereof. The organic acid is not particularly limited, but examples thereof include sulfonic acid, carboxylic acid, phosphoric acid and the like. Among those, the sulfonic acid or the carboxylic acid is preferable, and the sulfonic acid is more preferable. A method of introducing organic acid into a surface of an abrasive grain is not particularly limited, and the known methods can be used.

An average primary particle size of the abrasive grain is preferably 5 nm or more, more preferably 7 nm or more, and still more preferably 10 nm or more. Within this range, the polishing speed is increased. In addition, the average primary particle size of the abrasive grain is preferably 50 nm or less, more preferably 40 nm or less, and still more preferably 30 nm or less. Within this range, the number of defects on the surface after the treatment is further reduced. In addition, the value of the average primary particle size of the abrasive grain can be calculated on the assumption that the shape of the silica particle is a true sphere, based on a specific surface area of the abrasive grain measured by a BET method.

An average secondary particle size of the abrasive grain in water is preferably 5 nm or more, more preferably 10 nm or more, and still more preferably 20 nm or more. Within this range, the polishing speed is increased. In addition, the average secondary particle size of the abrasive grain in water is preferably 100 nm or less, more preferably 90 nm or less, and still more preferably 80 nm or less. Within this range, the number of defects on the surface after the treatment is further reduced. In addition, the value of the average secondary particle size of abrasive grain can be calculated based on the specific surface area of the abrasive grain measured by a light scattering method using a laser beam.

The abrasive grain may be either a synthetic product or a commercially available product.

Note that the abrasive grain may be used alone or in combination of two or more.

The lower limit of the content of the abrasive grain in the polishing composition according to an embodiment of the present invention is not particularly limited, but preferably more than 0.01% by mass, more preferably 0.1% by mass or more, and still more preferably 1% by mass or more based on the total mass of the polishing composition. Within this range, the polishing speed is increased. In addition, the upper limit of the content of the abrasive grain in the polishing composition according to an embodiment of the present invention is not particularly limited, but preferably 10% by mass or less, more preferably 5% by mass or less, and still more preferably 3% by mass or less based on the total mass of the polishing composition. Within this range, the number of defects on the surface after the treatment can be further reduced, and the cost can also be reduced.

In the polishing composition according to an embodiment of the present invention, the content ratio of the abrasive grain and the nitrogen-containing sulfonic acid compound is not particularly limited, but from the viewpoint of increasing the polishing speed, the content (part by mass) of the abrasive grain to the content (part by mass) of the nitrogen-containing sulfonic acid compound (content (part by mass) of the abrasive grain/content (part by mass) of the nitrogen-containing sulfonic acid compound) is preferably 0.5 or more, more preferably 1 or more, and still more preferably 1.5 or more. In addition, in the polishing composition according to an embodiment of the present invention, the content ratio of the abrasive grain and the nitrogen-containing sulfonic acid compound is preferably 10 or less, more preferably 5 or less, and still more preferably 3 or less from the viewpoint of enhancing the tungsten dissolution inhibiting effect.

In addition, the composition for surface treatment according to an embodiment of the present invention may include the abrasive grain. The abrasive grain may have a function of mechanically removing the residues of the object to be subjected to surface treatment.

However, the content of the composition for surface treatment according to an embodiment of the present invention is preferably as low as possible because the abrasive grain may be a cause of residues, and it is particularly preferable that the composition for surface treatment is substantially free of the abrasive grain. In the present specification, the “substantially no containing an abrasive grain” means that the content of the abrasive grain is 0.01% by mass or less based on the total mass of the composition for surface treatment.

[pH Adjusting Agent]

The tungsten dissolution inhibitor (tungsten dissolution inhibitor composition) according to an embodiment of the present invention may further include a pH adjusting agent.

In particular, the polishing composition according to an embodiment of the present invention and the composition for surface treatment according to an embodiment of the present invention preferably further include the pH adjusting agent. The pH adjusting agent is added mainly for the purpose of adjusting the pH of the composition for surface treatment.

The pH adjusting agent is not particularly limited as long as it is a compound having a pH adjusting function, and the known compounds can be used. Examples of the pH adjusting agent include acids, alkalis, salts thereof, and the like, and among those, the acids are particularly preferable. In addition, alkali and a salt of acid or the alkali are not particularly limited, but are preferably used in combination with the acid, and particularly preferably used in combination with the acid and used to lower the pH as a whole. These may be any of inorganic compounds and organic compounds.

In the present specification, the acid does not include the above-described nitrogen-containing sulfonic acid compound and the anionic polymer dispersant. That is, the nitrogen-containing sulfonic acid compound or the anionic polymer dispersant are treated as being different from acid as an additive described herein.

As the acid, either an inorganic acid or an organic acid may be used. The inorganic acid is not particularly limited, but examples thereof include sulfuric acid, nitric acid, boric acid, carbonic acid, hypophosphorous acid, phosphorous acid, phosphoric acid, and the like. The organic acid is not particularly limited, and examples thereof include carboxylic acid such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid, and methanesulfonic acid, ethanesulfonic acid, isethionic acid and the like. Among those, the maleic acid or the nitric acid is more preferable, and the maleic acid is still more preferable.

The alkali is not particularly limited, and examples thereof include hydroxides of alkali metals such as potassium hydroxide, ammonia, quaternary ammonium salts such as tetramethyl ammonium and tetraethyl ammonium, amines such as ethylene diamine and piperazine and the like.

The salt of the acid or the alkali is not particularly limited, but examples thereof include carbonates, hydrogencarbonates, ammonium salts, potassium salts, sodium salts, lithium salts, and the like, of the acid or the alkali exemplified above.

Note that the pH adjusting agent may be used alone or in combination of two or more.

The content of the pH adjusting agent is not particularly limited, but is preferably 0.001% by mass or more, more preferably 0.005% by mass or more, and still more preferably 0.01% by mass or more based on the total mass of the tungsten dissolution inhibitor composition. Within this range, the excellent pH adjustment function can be obtained. In addition, the range of the preferable content is also the same as in the case where the tungsten dissolution inhibitor composition is the polishing composition or where the tungsten dissolution inhibitor composition is the composition for surface treatment. In the applications of the polishing composition and the composition for surface treatment, the number of defects on the surface after the treatment is further reduced. It is presumed that the reason is that the tungsten dissolution inhibiting effect is enhanced, and the effect of charging the surface of the polished object to be polished or the object to be subjected to surface treatment and the surface of residues with a positive charge is enhanced and the ease of adsorption of the anionic polymer dispersant is enhanced. In addition, the content of the pH adjusting agent is preferably 0.5% by mass or less, more preferably 0.25% by mass or less, still more preferably 0.1% by mass or less, and particularly preferably 0.05% by mass or less based on the total mass of the tungsten dissolution inhibitor composition (polishing composition, composition for surface treatment). Within this range, the excellent pH adjustment function can be obtained and the cost can be reduced. In addition, the range of the preferable content is also the same as in the case where the tungsten dissolution inhibitor composition is the polishing composition or where the tungsten dissolution inhibitor composition is the composition for surface treatment.

[Oxidizing Agent]

The tungsten dissolution inhibitor (tungsten dissolution inhibitor composition) according to an embodiment of the present invention may preferably further include an oxidizing agent.

In particular, the polishing composition according to an embodiment of the present invention may include an oxidizing agent. The oxidizing agent generally has a function of enhancing specific polishing characteristics depending on the formulation of the polishing composition and the type of the object to be polished such as a function of increasing a polishing speed and a function of enhancing a quality of a surface of an object to be polished after polishing by oxidizing the surface of the object to be polished.

The oxidizing agent is not particularly limited, but examples thereof include hydrogen peroxide, sodium peroxide, barium peroxide, ozone water, silver (II) salt, iron (III) salt, permanganic acid, chromic acid, dichromic acid, peroxodisulfuric acid, peroxophosphoric acid, peroxosulfuric acid, perboric acid, performic acid, peracetic acid, perbenzoic acid, perphthalic acid, hypochlorous acid, hypobromous acid, hypoiodic acid, chloric acid, hypochlorous acid, perchloric acid, bromic acid, iodic acid, periodic acid, persulfuric acid, dichloroisocyanuric acid, and salts thereof and the like. Among those, the hydrogen peroxide is preferable. Note that the oxidizing agent may be used alone or in combination of two or more.

In the polishing composition according to an embodiment of the present invention, the content of the oxidizing agent is not particularly limited, but is preferably 5% by mass or less and more preferably 2% by mass or less based on the total mass of the polishing composition (lower limit is 0% by mass).

However, the composition for surface treatment according to an embodiment of the present invention is preferably substantially free of the oxidizing agent. In the present specification, the “substantially no containing an oxidizing agent” means that the content of the oxidizing agent is 0.0001% by mass or less based on the total mass of the tungsten dissolution inhibitor. Among those, it is particularly preferable that the content of the oxidizing agent is 0.00002% by mass or less, and it is most preferable that the content of the oxidizing agent is not included at all (lower limit is 0% by mass). The reason is that in applications of the composition for surface treatment according to an embodiment of the present invention, the oxidizing agent may be a cause of residues.

[Other Components]

The tungsten dissolution inhibitor (tungsten dissolution inhibitor composition) according to an embodiment of the present invention may further contain other components other than those described above, within the range in which the effects of the present invention are not inhibited.

In particular, the polishing composition according to an embodiment of the present invention and the composition for surface treatment according to an embodiment of the present invention may further include other components in order to impart a desired function according to the purpose of use.

Other components are not particularly limited, and for example, components used for the known polishing composition or composition for surface treatment such as a wetting agent, a surfactant, a chelating agent, an antiseptic agent, an antifungal agent, a dissolved gas, and a reducing agent may be appropriately selected. However, in particular, in the applications of the composition for surface treatment, components other than the components required to express the intended function may be a cause of residues, and as a result, it is preferable that the content of the components is preferably as low as possible and it is particularly preferable that the components are not substantially contained.

[pH]

The pH of the tungsten dissolution inhibitor (tungsten dissolution inhibitor composition) according to an embodiment of the present invention is not particularly limited, but is preferably less than 7, more preferably less than 6, and still more preferably 4 or less, particularly preferably 3 or less, and most preferably 2.5 or less. When the pH is less than 7, that is, in case of an acidic region, the dissolution inhibiting effect of the tungsten-containing material is enhanced. It is presumed that the reason is that the coordination to the tungsten-containing material tends to occur due to the nitrogen atom of the nitrogen-containing sulfonic acid compound, and the formation of an insoluble complex on the surface of the material is further promoted to further inhibit the formation of tungsten hydrate. In addition, the range of the preferable content is also the same as in the case where the tungsten dissolution inhibitor composition is the polishing composition or where the tungsten dissolution inhibitor composition is the composition for surface treatment. In the applications of the polishing composition and in the applications of the composition for surface treatment, the removal performance of the residues is enhanced. It is presumed that the reason is that the effect of charging the surface of the polished object to be polished or the surface of the object to be subjected to surface treatment and the surface of residues with a positive charge is enhanced and the ease of adsorption of the above-described sulfonic acid group-containing polymer is enhanced. The pH of the tungsten dissolution inhibitor composition according to an embodiment of the present invention is not particularly limited, but is preferably 1 or more, more preferably 1.5 or more, and still more preferably 2 or more. Within this range, the amount of use of the pH adjusting agent can be further reduced, and the cost can be reduced. In addition, when the abrasive grain is included, the dispersion stability of the abrasive grain is enhanced. Thereby, one example of the preferred tungsten dissolution inhibitor (tungsten dissolving agent composition) of the present invention contains a dispersing medium, the dispersing medium contains water, and the pH is less than 7. In addition, the range of the preferable content is also the same as in the case where the tungsten dissolution inhibitor composition is the polishing composition or where the tungsten dissolution inhibitor composition is the composition for surface treatment. Therefore, it is preferable that the polishing composition according to an embodiment of the present invention includes the dispersing medium, the dispersing medium includes water, and the pH is less than 7. In addition, it is preferable that the composition for surface treatment according to an embodiment of the present invention includes the dispersing medium, the dispersing medium includes water, and the pH is less than 7.

[Dissolution Inhibiting Effect]

The tungsten dissolution inhibitor according to an embodiment of the present invention preferably has the high dissolution inhibiting effect of the tungsten-containing material. Specifically, when a tungsten wafer (size: 32 mm×32 mm) is immersed and etched at 60° C. for 10 minutes in a state where 300 mL of the tungsten dissolution inhibitor according to an embodiment of the present invention is stirred at 300 rpm, the difference in thickness (film thickness) of the tungsten wafer before and after the etching test is preferably 5 Å or less (lower limit is 0 Å).

When the tungsten dissolution inhibitor (tungsten dissolution inhibitor composition) according to an embodiment of the present invention is used for the applications of the polishing composition, the difference in the thickness (film thickness) of the tungsten wafer before and after the etching test in the polishing composition according to an embodiment of the present invention is more preferably 4.5 Å or less, still more preferably 3.9 Å or less, even more preferably 3.3 Å or less, particularly preferably 3.0 Å or less, and most preferably 2.5 Å or less (lower limit is 0 Å).

When the tungsten dissolution inhibitor (tungsten dissolution inhibitor composition) according to an embodiment of the present invention is used for the applications of the composition for surface treatment, the difference in the thickness (film thickness) of the tungsten wafer before and after the etching test in the composition for surface treatment according to an embodiment of the present invention is more preferably 2.5 Å or less, still more preferably 1.7 Å or less, even more preferably 1.5 Å or less, particularly preferably 1.3 Å or less, and most preferably 1.2 Å or less (lower limit is 0 Å).

[Defect Reduction Effect]

It is preferable that the number of defects on the surface of the tungsten-containing material is as small as possible after the treatment of the tungsten-containing material using the tungsten dissolution inhibitor (tungsten dissolution inhibitor composition) according to an embodiment of the present invention. Here, the defects represent surface flaws or roughness due to the corrosion (dissolution) of the tungsten-containing material, and surface irregularities such as residues remaining on the surface.

When the tungsten dissolution inhibitor (tungsten dissolution inhibitor composition) according to an embodiment of the present invention is used in the application of the polishing composition, the number of defects on the surface of the tungsten-containing material after the treatment is preferably 185 or less, more preferably 110 or less, still more preferably 50 or less, and particularly preferably 35 or less (lower limit is 0).

When the tungsten dissolution inhibitor (tungsten dissolution inhibitor composition) according to an embodiment of the present invention is used in the applications of the composition for surface treatment, the number of defects on the surface of the tungsten-containing material after the treatment is preferably 100 or less, more preferably 50 or less, still more preferably 20 or less, and particularly preferably 15 or less (lower limit is 0).

In addition, after performing the polishing treatment or the surface treatment by the method as described in Example, the number of defects employs a value measured by the method as described in Example.

<Method of Producing Tungsten Dissolution Inhibitor Composition, Polishing Composition and Composition for Surface Treatment>

Another aspect of the present invention relates to a method of producing a tungsten dissolution inhibitor composition, which contains a mixture of the nitrogen-containing sulfonic acid compound with components other than the nitrogen-containing sulfonic acid compound. The components other than the nitrogen-containing sulfonic acid compound preferably include a dispersing medium. The same goes for the case where the tungsten dissolution inhibitor composition is a polishing composition or a composition for surface treatment.

A method for producing a polishing composition is preferably a method of producing a polishing composition which contains a mixture of a nitrogen-containing sulfonic acid compound with a dispersing medium and is used for polishing an object to be polished having a tungsten-containing layer. In addition, a method of producing a polishing composition is particularly preferably a method of producing a polishing composition which contains a mixture of a nitrogen-containing sulfonic acid compound with a dispersing medium and an abrasive grain and is used for polishing an object to be polished having a tungsten-containing layer.

In addition, a method of producing a composition for surface treatment is particularly preferably a method of producing a composition for surface treatment which contains a mixture of a nitrogen-containing sulfonic acid compound with a dispersing medium and is used for treating a surface of a polished object to be polished having a tungsten-containing layer.

A mixing method in the case of mixing each component is not particularly limited, and the known methods can be used appropriately. In addition, a mixing temperature is not particularly limited, but generally preferably 10 to 40° C. and heating may be performed to increase a rate of dissolution. In addition, a mixing time is not particularly limited.

In the method of producing a tungsten dissolution inhibitor composition, the preferred embodiments (type, characteristics, structure, content, and the like) of each component containing the nitrogen-containing sulfonic acid compound are the same as those in the description of the respective components. In addition, various characteristics including preferred characteristics of the tungsten dissolution inhibitor composition to be produced are also the same as the description of the tungsten dissolution inhibitor.

<Dissolution Inhibiting Method>

Another aspect of the present invention relates to a tungsten dissolution inhibiting method which inhibits a dissolution of a tungsten-containing material by bringing the tungsten dissolution inhibitor into contact with the tungsten-containing material.

The method, apparatus, and conditions for bringing a tungsten-containing material into contact with a tungsten dissolution inhibitor are not particularly limited, and the known methods, apparatuses, and conditions can be appropriately used.

<Polishing Method>

Another aspect of the present invention relates to a polishing method which polishes an object to be polished having a tungsten-containing layer by using the above-described polishing composition or by producing a polishing composition by the above-described production method and then using the obtained polishing composition.

The polishing apparatus and the polishing conditions are not particularly limited, and the known apparatuses and conditions can be appropriately used.

As the polishing apparatus, a general polishing apparatus which includes a holder holding an object to be polished, a motor which can change the revolution number and the like mounted therein and a polishing table to which a polishing pad (polishing cloth) can be attached can be used. As the polishing apparatus, either a single-side polishing apparatus or a double-side polishing apparatus may be used. As the polishing pad, general non-woven fabric, polyurethane, porous fluororesin and the like can be used without particular limitation. The polishing pad is preferably subjected to groove processing so that a polishing liquid is accumulated.

The polishing conditions are not particularly limited, and appropriate conditions can be appropriately set according to the characteristics of the polishing composition and the object to be polished. A polishing load is not particularly limited, but generally, preferably 0.1 psi or more and 10 psi or less, more preferably 0.5 psi or more and 8 psi or less, and still more preferably 1 psi or more and 6 psi or less per unit area. Within this range, damage to the substrate due to the load and the occurrence of defects such as scratches on the surface can be further suppressed while obtaining a high polishing speed. The revolution number of the table and the revolution number of the carrier are not particularly limited, but generally, each of them is preferably 10 rpm or more and 500 rpm or less, more preferably 20 rpm or more and 300 rpm or less, and still more preferably 30 rpm or more and 200 rpm or less. The revolution number of the table and the revolution number of the carrier may be the same or different, but it is preferable that the revolution number of the table is larger than that of the carrier. The method of supplying a polishing composition is also not particularly limited, and a method of continuously supplying (constant flow) a polishing composition with a pump or the like may be adopted. A supply amount (flow rate of the polishing composition) of the polishing composition may be any supply amount covering the entire object to be polished, and is not particularly limited, but generally, preferably 100 mL/min or more and 5000 mL/min or less. The polishing time is not particularly limited as long as it is appropriately set so as to obtain a target polishing result, but generally, preferably 5 seconds or more and 180 seconds or less.

After the polished object to be polished after the completion of the polishing may be cleaned with water, the surface of the polished object to be polished may be dried by removing water droplets attached to the surface thereof by a spin dryer, an air blow, or the like.

<Surface Treatment Method>

Another aspect of the present invention relates to a surface treatment method which contains performs surface treatment on the polished object to be polished (object to be subjected to surface treatment) having the tungsten-containing layer using the obtained composition for surface treatment by using the above-described composition for surface treatment or by producing a composition for surface treatment by the above-described production method and then using the obtained composition for surface treatment.

In the present specification, the surface treatment refers to treatment for reducing residues on the surface of the object to be subjected to surface treatment, and represents treatment for performing cleaning in a broad sense.

In the present specification, the “residues” refers to foreign matters attached to the surface of the polished object to be polished. The residues are not particularly limited, and examples thereof include organic residues, particle residues derived from abrasive grains, residues derived from the object to be polished, residues made of a mixture of two or more thereof, and the like. The organic residues represent a component made of organic substances such as a low molecular weight compound or a polymer compound, organic salts or the like, among foreign matters attached to the surface of the polished object to be polished. Examples of the organic residues include pad scraps generated from the pad used in a polishing process described below or in an optional rinse polishing process, components derived from additives contained in the polishing composition used in the polishing process or the rinse polishing composition used in the rinse polishing process, or the like. The number of residues can be confirmed by a wafer defect inspection apparatus SP-2 manufactured by KLA TENCOR Corporation. In addition, since colors and shapes largely differ depending on the type of residues, the type of residues can be visually judged by SEM observation. In addition, the type of residues may be judged based on an elemental analysis by energy dispersive X-ray analyzer (EDX) as needed.

The surface treatment method according to an embodiment of the present invention is performed by a method of brining a composition for surface treatment into direct contact with an object to be subjected to surface treatment. The surface treatment method, the surface treatment apparatus, and the surface treatment conditions are not particularly limited, and the known methods, apparatuses, and conditions can be appropriately used.

The surface treatment method is preferably a method by rinse polishing treatment or a method by cleaning treatment, and more preferably a method by rinse polishing treatment.

In the present specification, the rinse polishing treatment is treatment which is performed on the polishing table (platen) to which the polishing pad is attached to remove the residues on the surface of the polished object to be polished by a friction force (physical action) by the polishing pad and a chemical action by the composition for surface treatment. A specific example of the rinse polishing treatment includes treatment which performs final polishing (finishing polishing) on the object to be polished, and then provides the polished object to be polished on the polishing table (platen) of the polishing apparatus, brings the polishing pad into contact with the polished object to be polished, and relatively slides the polished object to be polished and the polishing pad while supplying the composition for surface treatment to the contacted portion.

The rinse polishing apparatus and the rinse polishing conditions are not particularly limited, and the known apparatuses and conditions can be appropriately used.

As the rinse polishing apparatus, for example, the same polishing apparatus or polishing pad as those described in the above-described polishing method can be used. In addition, the rinse polishing apparatus is preferably provided with a discharge nozzle of the composition for surface treatment in addition to a discharge nozzle of the polishing composition.

The rinse polishing conditions are not particularly limited, and appropriate conditions can be appropriately set according to the characteristics of the composition for surface treatment and the polished object to be polished. A rinse polishing load is not particularly limited, but generally, preferably 0.1 psi or more and 10 psi or less, more preferably 0.5 psi or more and 8 psi or less, and still more preferably 1 psi or more and 6 psi or less per unit area of the substrate. Within this range, damage to the substrate due to the load and the occurrence of defects such as scratches on the surface can be further suppressed while obtaining a high residue-removing effect. The revolution number of the table and the revolution number of the carrier are not particularly limited, but generally, each of them is preferably 10 rpm or more and 500 rpm or less, more preferably 20 rpm or more and 300 rpm or less, and still more preferably 30 rpm or more and 200 rpm or less. The revolution number of the table and the revolution number of the carrier may be the same or different, but it is preferable that the revolution number of the table is larger than that of the carrier. The method of supplying a composition for surface treatment is also not particularly limited, and a method of continuously supplying (constant flow) a composition for surface treatment with a pump or the like may be adopted. A supply amount (flow rate of the composition for surface treatment) of the composition for surface treatment may be a supply amount covering the entire polished object to be polished, and is not particularly limited, but generally, preferably 100 mL/min or more and 5000 mL/min or less. The rinse polishing treatment time is not particularly limited as long as it is appropriately set so as to obtain a target residue-removing effect, but generally, preferably 5 seconds or more and 180 seconds or less.

In the present specification, the cleaning treatment represents treatment removing the residues on the surface of the object to be subjected to surface treatment by the chemical action mainly by the composition for surface treatment, which is performed in a state in which the polished object to be polished (object to be subjected to surface treatment) is removed from the polishing table (platen). A specific example of the cleaning treatment includes treatment which performs the final polishing (finishing polishing) on the object to be polished or performs the final polishing followed by the rinse polishing treatment, and then removes the polished object to be polished from the polishing table (platen) and brings the polished object to be polished into contact with the composition for surface treatment. A means for applying a frictional force (physical action) to the surface of the polished object to be polished may be further used in the state where the composition for surface treatment contacts the polished object to be polished.

The cleaning treatment method, the cleaning treatment apparatus, and the cleaning treatment conditions are not particularly limited, and the known methods, apparatuses, and conditions can be appropriately used.

The cleaning treatment method is not particularly limited, but includes a method of immersing a polished object to be polished in a composition for surface treatment and performing ultrasonic treatment on the polished object to be polished as necessary, a method of bringing a cleaning brush into contact with an object to be subjected to surface treatment in a state where a polished object to be polished is held and rubbing a surface of a polished object to be polished with a brush while supplying a composition for surface treatment to the contacted portion, or the like.

The cleaning apparatus is not particularly limited, and the known apparatuses can be appropriately used.

The cleaning conditions are not particularly limited, and appropriate conditions can be appropriately set according to the characteristics of the polishing composition and the polished object to be polished.

The cleaning with water may be performed before, after, or before and after the surface treatment method according to an embodiment of the present invention. Thereafter, the water droplets attached to the surface of the polished object to be polished may be removed by a spin dryer, an air blow or the like and dried.

<Method of Manufacturing Semiconductor Substrate>

Another aspect of the present invention relates to a method of manufacturing a semiconductor substrate including inhibiting a dissolution of a tungsten-containing material by bringing the tungsten dissolution inhibitor into contact with the tungsten-containing layer. That is, the aspect relates to a method of manufacturing a semiconductor substrate including applying these tungsten dissolution inhibitors to a substrate material containing tungsten used for forming the semiconductor substrate which is an object to be treated.

In the case of using the polishing composition according to an embodiment of the present invention, the method of manufacturing a semiconductor substrate preferably includes polishing an object to be polished having a tungsten-containing layer by the above-described polishing method (polishing process). In addition, in the manufacturing method, a process which can be adopted in the known method of manufacturing a semiconductor substrate can be appropriately adopted for other process.

In the case of using the composition for surface treatment according to an embodiment of the present invention, the method of manufacturing a semiconductor substrate preferably includes treating a surface of a polished object to be polished having a tungsten-containing layer by the above-described polishing method (surface treating process). In addition, in the manufacturing method, a process which can be adopted in the known method of manufacturing a semiconductor substrate can be appropriately adopted for other process.

The embodiments of the present invention have been described in detail, but are illustrative and exemplary and are not restrictive, and it is obvious that the scope of the present invention should be interpreted by the appended claims.

The present invention includes the following aspects and forms.

1. Tungsten dissolution inhibitor which contains a sulfonic acid compound or a salt thereof containing a nitrogen atom and having a molecular weight of less than 1,000;

2. The tungsten dissolution inhibitor according to the above 1., in which the sulfonic acid compound or the salt thereof is represented by the following formula (1):

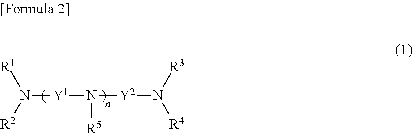

in the formula (1),

Y¹ and Y² each independently represent a linear or branched alkylene group having 1 or more and 5 or less carbon atoms,

n is an integer of 0 or more and 4 or less,

R¹ to R⁵ each independently represent a hydrogen atom, a sulfonic acid (salt) group or a substituted or unsubstituted linear or branched alkyl group having 1 or more and 5 or less carbon atoms, and

in this case, at least one of R¹ to R⁵ is a sulfonic acid (salt) group or an alkyl group substituted with the sulfonic acid (salt) group;

3. The tungsten dissolution inhibitor according to the above 2., in which in the above formula (1), at least four of R¹ to R⁵ are a sulfonic acid (salt) group or an alkyl group substituted with the sulfonic acid (salt) group;

4. The tungsten dissolution inhibitor according to any one of the above 1. to 3., further including a dispersing medium;

5. A polishing composition which is the tungsten dissolution inhibitor according to the above 4., further including an abrasive grain, and is used for polishing an object to be polished having a tungsten-containing layer;

6. The polishing composition according to the above 5., further including a polymer compound which has an anionic functional group or a group of a salt thereof and has a weight average molecular weight of 1,000 or more;

7. The polishing composition according to the above 5. or 6., in which the dispersing medium contains water and pH is less than 7;

8. A method of producing a polishing composition including mixing a sulfonic acid compound or a salt thereof containing a nitrogen atom and having a molecular weight of less than 1,000 with a dispersing medium and an abrasive grain, in which the polishing composition is used for polishing an object to be polished having a tungsten-containing layer;

9. A polishing method including polishing an object to be polished having a tungsten-containing layer by using the polishing composition according to any one of the above 5. to 7., or by producing a polishing composition by the production method according to the above 8. and then using the obtained polishing composition;

10. A method of manufacturing a semiconductor substrate includes polishing an object to be polished having a tungsten-containing layer by the polishing method according to the above 9;

11. A composition for surface treatment which is the tungsten dissolution inhibitor according to the above 4. is used for treating a surface of a polished object to be polished having a tungsten-containing layer;

12. The composition for surface treatment according to the above 11., being substantially free of an abrasive grain;

13. The composition for surface treatment according to the above 11. or 12., further including a polymer compound which has an anionic functional group or a group of a salt thereof and has a weight average molecular weight of 1,000 or more;

14. The composition for surface treatment according to any one of the above 11. to 13., being substantially free of an oxidizing agent;

15. The composition for surface treatment according to any one of the above 11. to 14., in which the dispersing medium contains water and pH is less than 7;

16. A method of producing a composition for surface treatment including mixing a sulfonic acid compound or a salt thereof containing a nitrogen atom and having a molecular weight of less than 1,000 with a dispersing medium, in which the composition for surface treatment is used for treating a surface of a polished object to be polished having a tungsten-containing layer;

17. A surface treatment method including performing surface treating on a polished object to be polished having a tungsten-containing layer by using the composition for surface treatment according to any one of the above 11. to 15., or by producing a composition for surface treatment by the production method according to the above 16. and then using the obtained composition for surface treatment;

18. The surface treatment method according to the above 17., in which the surface treatment is rinse polishing treatment or cleaning treatment; and

19. A method of manufacturing a semiconductor substrate including treating a surface of a polished object to be polished having a tungsten-containing layer by the surface treatment method according to the above 17. or 18.

### EXAMPLES

The present invention will be described in more detail with reference to Examples and Comparative Examples below. However, the technical scope of the present invention is not limited to the following Examples. In addition, unless otherwise stated, “%” and “part” each mean “% by mass” and “part by mass”.

<Composition for Surface Treatment>

[Preparation of Composition for Surface Treatment]

(Preparation of Composition for Surface Treatment A-1)

By mixing maleic acid as a pH adjusting agent with water (deionized water) as a dispersing medium in an amount so that the content of maleic acid is 0.01% by mass based on a total mass of composition for surface treatment, a composition for surface treatment A-1 was prepared. The pH of the composition for surface treatment (liquid temperature: 25° C.) confirmed by a pH meter (manufactured by Horiba, Ltd., product name: LAQUA (trademark)) was 2.1.

(Preparation of Composition for Surface Treatment A-2)

By mixing polystyrene sulfonic acid (Mw=10,000) as an anionic polymer dispersant with maleic acid as a pH adjusting agent and water (deionized water) in an amount so that the content of polystyrene sulfonic acid is 0.5% by mass based on a total mass of composition for surface treatment and the content of maleic acid is 0.01% by mass based on a total mass of composition for surface treatment, a composition for surface treatment A-2 was prepared. The pH of the composition for surface treatment (liquid temperature: 25° C.) confirmed by a pH meter (manufactured by Horiba, Ltd., product name: LAQUA (trademark)) was 2.1.

(Preparation of Composition for Surface Treatment A-3 to A-19)

By mixing a tungsten dissolution inhibitor compound described in the following Table 1 with maleic acid as a pH adjusting agent and water (deionized water) in an amount so that the content of the tungsten dissolution inhibitor compound is 1% by mass based on a total mass of composition for surface treatment and the content of maleic acid is 0.01% by mass based on a total mass of composition for surface treatment, compositions for surface treatment A-3 to A-19 were each prepared. All the pHs confirmed by a pH meter (manufactured by Horiba, Ltd., product name: LAQUA (trademark)) of the compositions for surface treatment (liquid temperature: 25° C.) were 2.1.

(Preparation of Composition for Surface Treatment A-20 to A-22)

By mixing a tungsten dissolution inhibitor compound described in the following Table 1 with polystyrene sulfonic acid (Mw=10,000) as an anionic polymer dispersant, maleic acid as a pH adjusting agent and water (deionized water) in an amount so that the content of the tungsten dissolution inhibitor compound is 1% by mass based on a total mass of composition for surface treatment, the content of polystyrene sulfonic acid is 0.5% by mass based on a total mass of composition for surface treatment, and the content of maleic acid is 0.01% by mass based on a total mass of composition for surface treatment, compositions for surface treatment A-20 to A-22 were each prepared. All the pHs confirmed by a pH meter (manufactured by Horiba, Ltd., product name: LAQUA (trademark)) of the compositions for surface treatment (liquid temperature: 25° C.) were 2.1.

(Molecular Weight of Tungsten Dissolution Inhibitor Compound)

The molecular weight of the tungsten dissolution inhibitor compound was calculated from the sum of atomic weights.

(Measurement of Weight Average Molecular Weight of Anionic Polymer Dispersant)

As the weight average molecular weight (Mw) of the polystyrene sulfonic acid which is the anionic polymer dispersant, a value of weight average molecular weight (in terms of polyethylene glycol) measured by gel permeation chromatography (GPC) was used. The weight average molecular weight was measured by the following apparatuses and conditions:

GPC apparatus: manufactured by Shimadzu Corporation

Model: Prominence+ELSD detector (ELSD-LTII)

Column: VP-ODS (manufactured by Shimadzu Corporation)

Mobile phase A: MeOH

B: Aqueous solution of 1% of acetic acid

Flow rate: 1 mL/min

Detector: ELSD temp. 40° C., Gain 8, N₂GAS 350 kPa

Oven temperature: 40° C.

Injection amount: 40 μL

Formulation of each composition for surface treatment is shown in Table 1.

[Evaluation of Tungsten Dissolution Inhibiting Effect]

As an indicator of the dissolution inhibiting effect of the tungsten layer, an etching test was performed by the following operation. That is, a tungsten wafer (size: 32 mm×32 mm) was immersed at 60° C. for 10 minutes in a sample container in which 300 mL of each composition for surface treatment was stirred at 300 rpm. After the immersion, the tungsten wafer was cleaned with pure water for 30 seconds and dried by air blow drying using an air gun. The thickness (film thickness) of the tungsten wafer before and after the etching test was measured by a manual sheet resistor (VR-120, manufactured by Hitachi Kokusai Electric Co., Ltd.). The difference in thickness (film thickness) of the tungsten wafer before and after the etching test was calculated as a tungsten etching amount (A). It means that the smaller the tungsten etching amount, the higher the tungsten dissolution inhibiting effect. The results are shown in Table 2.

[Evaluation of the Number of Defects]

(CMP Process)

For a substrate (hereinafter, even referred to as a W substrate) which has a tungsten (W) layer grown on a TEOS wafer by a CVD method, as a semiconductor substrate, the surface of the substrate on a side having the W layer was polished under the following conditions by using a polishing composition M (composition: 4% by mass of sulfonic acid-modified colloidal silica (prepared by a method described in “sulfonic acid-functionalized silica through quantitative oxidation of thiol groups”, Chem. Commun. 246-247(2003), primary particle size of 30 nm, secondary particle size of 60 nm), 1% by mass of ammonium sulfate, 0.018% by mass of aqueous maleic acid solution of a concentration of 30% by mass, solvent: water). Here, as the W substrate, a 300 mm wafer was used;

—Polishing Apparatus and Polishing Condition—

Polishing apparatus: FREX 300E manufactured by Ebara Co., Ltd.

Polishing pad: Rigid polyurethane pad IC1010 manufactured by Nitta Haas Co., Ltd.

Polishing pressure: 2.0 psi (1 psi=6894.76 Pa, and so forth)

The revolution number of polishing table: 63 rpm

The revolution number of head: 57 rpm

Supply of polishing composition M: Constant flow

Supply amount of polishing composition: 300 mL/min

Polishing time: 60 seconds.

(Rinse Polishing Treatment Process)

After the substrate surface on the side having the W layer was polished in the CMP process, the polished W substrate was removed from the polishing table (platen).

Subsequently, in the same polishing apparatus, the polished W substrate was mounted on another polishing table (platen), and the following rinse polishing treatment was performed on each of the surfaces of the substrates on the side having the W layer;

—Rinse Polishing Apparatus and Rinse Polishing Condition—

Polishing apparatus: FREX 300E manufactured by Ebara Co., Ltd.

Polishing pad: Rigid polyurethane pad IC1010 manufactured by Nitta Haas Co., Ltd.

Polishing pressure: 2.0 psi (1 psi=6894.76 Pa, and so forth)

The revolution number of polishing table: 63 rpm

The revolution number of head: 57 rpm

Supply of composition for surface treatments A-1 to A-22: Constant flow

Supply amount of composition for surface treatment: 300 mL/min

Rinse polishing treatment time: 60 seconds.

(Water Cleaning Process)

After the rinse polishing is performed, on a cleaning unit, each polished W substrate subjected to the rinse polishing treatment above obtained was cleaned for 60 seconds by using a PVA brush while applying deionized water (DIW) thereto. Thereafter, the polished W substrates were dried with a spin dryer for 30 seconds.

(Measurement of the Number of Defects)

The number of defects of 0.13 μm or more was measured for each of the obtained polished W substrates after the water cleaning process. The number of defects was measured using a wafer defect inspection apparatus SP-2 manufactured by KLA TENCOR Corporation. The measurement was performed on a remaining part by removing a part having a width of 5 mm from an outer peripheral end (when an outer peripheral end is 0 mm, a part from 0 mm in width to 5 mm in width) of one side of the polished W substrate (surface of the substrate on the side having the W layer). It means that the smaller the number of defects, the smaller the number of scratches or roughness of the surface caused by the dissolution of tungsten or the number of residues remaining on the surface, and the smaller the disturbance of the surface. The results are shown in Table 2.

TABLE 1
Formulation of each composition for surface treatment

| | | | | | pH adjusting | | |
|---|---|---|---|---|---|---|---|
| | | | | | agent | | |
| | Tungsten dissolution inhibitor compound | | Anionic polymer dispersant | | (Maleic acid) | | |
| Composition | | Content | | Content | Content | | |
| for surface | | [% by | | [% by | [% by | | |
| treatment No. | Type | mass] | Type | mass] | mass] | pH | |
| A-1 | None | 0 | None | 0 | 0.01 | 2.1 | Comparative Example |
| A-2 | None | 0 | Polystyrene sulfonic acid | 0.5 | 0.01 | 2.1 | Comparative Example |
| A-3 | Phenylphosphonic acid | 1 | None | 0 | 0.01 | 2.1 | Comparative Example |
| A-4 | Ethyl phosphate | 1 | None | 0 | 0.01 | 2.1 | Comparative Example |
| A-5 | Butyl phosphate | 1 | None | 0 | 0.01 | 2.1 | Comparative Example |
| A-6 | Octyl phosphate | 1 | None | 0 | 0.01 | 2.1 | Comparative Example |
| A-7 | Thioglycolic acid | 1 | None | 0 | 0.01 | 2.1 | Comparative Example |
| A-8 | Ammonium thioglycollate | 1 | None | 0 | 0.01 | 2.1 | Comparative Example |
| A-9 | Hydroxy ethylidene diphosphonic acid | 1 | None | 0 | 0.01 | 2.1 | Comparative Example |
| A-10 | Triethylene tetramine hexaacetic acid | 1 | None | 0 | 0.01 | 2.1 | Comparative Example |
| A-11 | Ethylene diamine tetraacetic acid | 1 | None | 0 | 0.01 | 2.1 | Comparative Example |
| A-12 | Hydroxy ethylimino diacetic acid | 1 | None | 0 | 0.01 | 2.1 | Comparative Example |
| A-13 | Diethylene triamine pentaacetic acid | 1 | None | 0 | 0.01 | 2.1 | Comparative Example |
| A-14 | N,N-bis (2-hydroxyethyl)-2-amino ethane | 1 | None | 0 | 0.01 | 2.1 | Inventive |
| | sulfonic acid | | | | | | |
| A-15 | 2-amino-1-naphthalenesulfonic acid | 1 | None | 0 | 0.01 | 2.1 | Inventive |
| A-16 | 2-aminoethanesulfonic acid | 1 | None | 0 | 0.01 | 2.1 | Inventive |
| A-17 | Ethylene diamine tetrasulfonic acid | 1 | None | 0 | 0.01 | 2.1 | Inventive |
| A-18 | Diethylene triamine pentasulfonic acid | 1 | None | 0 | 0.01 | 2.1 | Inventive |
| A-19 | Triethylene tetramine hexasulfonic acid | 1 | None | 0 | 0.01 | 2.1 | Inventive |
| A-20 | Ethylene diamine tetrasulfonic acid | 1 | Polystyrene sulfonic acid | 0.5 | 0.01 | 2.1 | Inventive |
| A-21 | Diethylene triamine pentasulfonic acid | 1 | Polystyrene sulfonic acid | 0.5 | 0.01 | 2.1 | Inventive |
| A-22 | Triethylene tetramine hexasulfonic acid | 1 | Polystyrene sulfonic acid | 0.5 | 0.01 | 2.1 | Inventive |

TABLE 2
Evaluation result of each composition for surface treatment

| Composition | | | |
|---|---|---|---|
| for surface | Tungsten | The number of | |
| treatment | etching amount | defects | |
| No. | [Å] | [Number] | |
| A-1 | 9.2 | 123 | Comparative Example |
| A-2 | 8.8 | 134 | Comparative Example |
| A-3 | 6.4 | 172 | Comparative Example |
| A-4 | 6.6 | 177 | Comparative Example |
| A-5 | 6.4 | 168 | Comparative Example |
| A-6 | 6.2 | 191 | Comparative Example |
| A-7 | 7.2 | 201 | Comparative Example |
| A-8 | 7.7 | 161 | Comparative Example |
| A-9 | 6.2 | 152 | Comparative Example |
| A-10 | 6.1 | 155 | Comparative Example |
| A-11 | 6.0 | 158 | Comparative Example |
| A-12 | 6.3 | 167 | Comparative Example |
| A-13 | 5.9 | 181 | Comparative Example |
| A-14 | 2.1 | 23 | Inventive |
| A-15 | 1.8 | 18 | Inventive |
| A-16 | 2.2 | 24 | Inventive |
| A-17 | 1.7 | 33 | Inventive |
| A-18 | 1.2 | 13 | Inventive |
| A-19 | 1.2 | 16 | Inventive |
| A-20 | 1.6 | 13 | Inventive |
| A-21 | 1.4 | 11 | Inventive |
| A-22 | 1.4 | 12 | Inventive |

It was confirmed as show from Tables 1 and 2 that the compositions for surface treatment A-14 to A-22 according to the present invention contain the sulfonic acid compound or the salt thereof which contains a nitrogen atom and has a molecular weight of less than 1,000, and the remarkable tungsten dissolution inhibiting effect is shown or the number of defects was significantly reduced by surface treatment using these compositions. On the other hand, it was confirmed that the compositions for surface treatment A-1 to A-13 not containing the sulfonic acid compound or the salt thereof which contains the nitrogen atom and has the molecular weight of less than 1,000, which deviate from the scope of the present invention, reduce the tungsten dissolution inhibiting effect, do not reduce the number of defects, increase the number of defects depending on the compound used in some cases, and cannot obtain a sufficient effect.

<Polishing Composition>

[Preparation of Polishing Composition]

(Preparation of Polishing Composition B-1)

By mixing colloidal silica (average primary particle size of 30 nm, average secondary particle size of 60 nm) as an abrasive grain, polystyrene sulfonic acid (Mw=10,000) as an anionic polymer dispersant, maleic acid as a pH adjusting agent, and water (deionized water) as a dispersing medium in an amount so that the content of the abrasive grain is 2% by mass based on the total mass of polishing composition, the content of the polystyrene sulfonic acid is 0.5% by mass based on the total mass of polishing composition, and the content of maleic acid is 0.01% by mass based on the total mass of polishing composition, a polishing composition B-1 was prepared. The pH of the polishing composition (liquid temperature: 25° C.) confirmed by a pH meter (manufactured by Horiba, Ltd., product name: LAQUA (trademark)) was 2.1.

(Preparation of Polishing Composition B-2)

By mixing colloidal silica (average primary particle size of 30 nm, average secondary particle size of 60 nm) as an abrasive grain, maleic acid as a pH adjusting agent, and water (deionized water) as a dispersing medium in an amount so that the content of the abrasive grain is 2% by mass based on the total mass of the polishing composition and the content of the maleic acid is 0.01% by mass based on the total mass of the polishing composition, a polishing composition B-2 was prepared. The pH of the polishing composition (liquid temperature: 25° C.) confirmed by a pH meter (manufactured by Horiba, Ltd., product name: LAQUA (trademark)) was 2.1.

(Preparation of Polishing Compositions B-3 to B-19)

By mixing colloidal silica (average primary particle size of 30 nm, average secondary particle size of 60 nm) as an abrasive grain, a tungsten dissolution inhibitor compound described in the following Table 3, polystyrene sulfonic acid (Mw=10,000) as an anionic polymer dispersant, maleic acid as a pH adjusting agent, hydrogen peroxide as an oxidizing agent, and water (deionized water) as a dispersing medium in an amount so that the content of the abrasive grain is 2% by mass based on the total mass of polishing composition, the content of the tungsten dissolution inhibitor compound is 1% by mass based on the total mass of polishing composition, the content of the polystyrene sulfonic acid is 0.5% by mass based on the total mass of polishing composition, the content of the maleic acid is 0.01% by mass based on the total mass of polishing composition, and the content of the hydrogen peroxide is 1% by mass based on the total mass of polishing composition, polishing compositions B-3 to B-19 were each prepared. All the pHs of the polishing compositions (liquid temperature: 25° C.) confirmed by a pH meter (manufactured by Horiba, Ltd., product name: LAQUA (trademark)) was 2.1.

(Preparation of Polishing Compositions B-20 to B-22)

By mixing colloidal silica (average primary particle size of 30 nm, average secondary particle size of 60 nm) as an abrasive grain, a tungsten dissolution inhibitor compound described in the following Table 3, maleic acid as a pH adjusting agent, and water (deionized water) as a dispersing medium in an amount so that the content of the abrasive grain is 2% by mass based on the total mass of polishing composition, the content of the tungsten dissolution inhibitor compound is 1% by mass based on the total mass of polishing composition, and the content of maleic acid is 0.01% by mass based on the total mass of polishing composition, polishing compositions B-20 to B-22 were each prepared. All the pHs of the polishing compositions (liquid temperature: 25° C.) confirmed by a pH meter (manufactured by Horiba, Ltd., product name: LAQUA (trademark)) was 2.1.

(Molecular Weight of Tungsten Dissolution Inhibitor Compound)

The molecular weight of the tungsten dissolution inhibitor compound was calculated from the sum of atomic weights.

(Measurement of Weight Average Molecular Weight of Anionic Polymer Dispersant)

As the weight average molecular weight of the polystyrene sulfonic acid which is the anionic polymer dispersant, a value of weight average molecular weight (in terms of polyethylene glycol) measured by gel permeation chromatography (GPC) was used. The weight average molecular weight was measured by the same apparatus and conditions as the measurement of the weight average molecular weight of the anionic polymer dispersant in the composition for surface treatment.

[Evaluation of Polishing speed]

(CMP Process)

For a substrate (W substrate) which has a tungsten (W) layer grown on a TEOS wafer by a CVD method, as the semiconductor substrate, the surface of the substrate on a side having the W layer was polished under the following conditions by using the each obtained polishing composition respectively. Here, as the W substrate, a 300 mm wafer was used;

—Polishing Apparatus and Polishing Condition—

Polishing apparatus: FREX 300E manufactured by Ebara Co., Ltd.

Polishing pad: Rigid polyurethane pad IC1010 manufactured by Nitta Haas Co., Ltd.

Polishing pressure: 2.0 psi (1 psi=6894.76 Pa, and so forth)

The revolution number of polishing table: 63 rpm

The revolution number of head: 57 rpm

Supply of polishing compositions B-1 to B-22: Constant flow

Supply amount of polishing composition: 300 mL/min

Polishing time: 60 seconds.

(Evaluation of Polishing Speed)

The thickness (film thickness) of the W substrate before and after the CMP process was measured by an optical film thickness measuring device (ASET-f5x: manufactured by KLA TENCOR Corporation). The difference in thickness (film thickness) of the W substrate before and after the CMP process was obtained and divided by the polishing time, and the unit was arranged, thereby calculating the polishing speed (A/min). The results are shown in Table 4.

[Evaluation of Tungsten Dissolution Inhibiting Effect]

As an indicator of the dissolution inhibiting effect of the tungsten layer, an etching test was performed by the following operation. That is, the W substrate (size: 32 mm×32 mm) was immersed at 60° C. for 10 minutes in a sample container in which 300 mL of each polishing composition was stirred at 300 rpm. After the immersion, the tungsten wafer was cleaned with pure water for 30 seconds and dried by air blow drying using an air gun. The thickness (film thickness) of the tungsten wafer before and after the etching test was measured by a manual sheet resistor (VR-120, manufactured by Hitachi Kokusai Electric Co., Ltd.). The difference in thickness (film thickness) of the tungsten wafer before and after the etching test was calculated as a tungsten etching amount (A). It means that the smaller the tungsten etching amount, the higher the tungsten dissolution inhibiting effect. The results are shown in Table 4.

[Evaluation of the Number of Defects]

(Measurement of the Number of Defects)

The number of defects of 0.13 μm or more was measured for each of the obtained polished W substrates after the CMP process. The number of defects was measured using a wafer defect inspection apparatus SP-2 manufactured by KLA TENCOR Corporation. The measurement was performed on a remaining part by removing a part having a width of 5 mm from an outer peripheral end (when an outer peripheral end is 0 mm, a part from 0 mm in width to 5 mm in width) of one side of the polished W substrate (surface of the substrate on the side having the W layer). It means that the smaller the number of defects, the smaller the number of scratches or roughness of the surface caused by the dissolution of tungsten or the number of residues remaining on the surface, and the smaller the disturbance of the surface. The results are shown in Table 4.

TABLE 3
Formulation of each polishing composition

| | Abrasive | | | |
|---|---|---|---|---|
| | grain | | | |
| | (Colloidal | | | |
| | silica) | Tungsten dissolution inhibitor compound | | |
| Polishing | Content | | Content | Anionic polymer |
| composition | [% by | | [% by | dispersant |
| No. | mass] | Type | mass] | Type |
| B-1 | 2 | None | 0 | Polystyrene sulfonic acid |
| B-2 | 2 | None | 0 | None |
| B-3 | 2 | Phenylphosphonic acid | 1 | Polystyrene sulfonic acid |
| B-4 | 2 | Ethyl phosphate | 1 | Polystyrene sulfonic acid |
| B-5 | 2 | Butyl phosphate | 1 | Polystyrene sulfonic acid |
| B-6 | 2 | Octyl phosphate | 1 | Polystyrene sulfonic acid |
| B-7 | 2 | Thioglycolic acid | 1 | Polystyrene sulfonic acid |
| B-8 | 2 | Ammonium thioglycollate | 1 | Polystyrene sulfonic acid |
| B-9 | 2 | Hydroxy ethylidene diphosphonic acid | 1 | Polystyrene sulfonic acid |
| B-10 | 2 | Triethylene tetramine hexaacetic acid | 1 | Polystyrene sulfonic acid |
| B-11 | 2 | Ethylene diamine tetraacetic acid | 1 | Polystyrene sulfonic acid |
| B-12 | 2 | Hydroxy ethylimino diacetic acid | 1 | Polystyrene sulfonic acid |
| B-13 | 2 | Diethylene triamine pentaacetic acid | 1 | Polystyrene sulfonic acid |
| B-14 | 2 | N,N-bis(2-hydroxyethyl)-2-aminoethane | 1 | Polystyrene sulfonic acid |
| | | sulfonic acid | | |
| B-15 | 2 | 2-amino-1-naphthalenesulfonic acid | 1 | Polystyrene sulfonic acid |
| B-16 | 2 | 2-aminoethanesulfonic acid | 1 | Polystyrene sulfonic acid |
| B-17 | 2 | Ethylene diamine tetrasulfonic acid | 1 | Polystyrene sulfonic acid |
| B-18 | 2 | Diethylene triamine pentasulfonic acid | 1 | Polystyrene sulfonic acid |
| B-19 | 2 | Triethylene tetramine hexasulfonic acid | 1 | Polystyrene sulfonic acid |
| B-20 | 2 | Ethylene diamine tetrasulfonic acid | 1 | None |
| B-21 | 2 | Diethylene triamine pentasulfonic acid | 1 | None |
| B-22 | 2 | Triethylene tetramine hexasulfonic acid | 1 | None |

| | | Oxidizing | pH adjusting | | |
|---|---|---|---|---|---|
| | | agent | agent | | |
| | Anionic polymer | (Hydrogen | (Maleic | | |
| | dispersant | peroxide) | acid) | | |
| Polishing | Content | Content | Content | | |
| composition | [% by | [% by | [% by | | |
| No. | mass] | mass] | mass] | pH | |
| B-1 | 0.5 | None | 0.01 | 2.1 | Comparative Example |
| B-2 | 0 | None | 0.01 | 2.1 | Comparative Example |
| B-3 | 0.5 | 1 | 0.01 | 2.1 | Comparative Example |
| B-4 | 0.5 | 1 | 0.01 | 2.1 | Comparative Example |
| B-5 | 0.5 | 1 | 0.01 | 2.1 | Comparative Example |
| B-6 | 0.5 | 1 | 0.01 | 2.1 | Comparative Example |
| B-7 | 0.5 | 1 | 0.01 | 2.1 | Comparative Example |
| B-8 | 0.5 | 1 | 0.01 | 2.1 | Comparative Example |
| B-9 | 0.5 | 1 | 0.01 | 2.1 | Comparative Example |
| B-10 | 0.5 | 1 | 0.01 | 2.1 | Comparative Example |
| B-11 | 0.5 | 1 | 0.01 | 2.1 | Comparative Example |
| B-12 | 0.5 | 1 | 0.01 | 2.1 | Comparative Example |
| B-13 | 0.5 | 1 | 0.01 | 2.1 | Comparative Example |
| B-14 | 0.5 | 1 | 0.01 | 2.1 | Inventive |
| B-15 | 0.5 | 1 | 0.01 | 2.1 | Inventive |
| B-16 | 0.5 | 1 | 0.01 | 2.1 | Inventive |
| B-17 | 0.5 | 1 | 0.01 | 2.1 | Inventive |
| B-18 | 0.5 | 1 | 0.01 | 2.1 | Inventive |
| B-19 | 0.5 | 1 | 0.01 | 2.1 | Inventive |
| B-20 | 0 | None | 0.01 | 2.1 | Inventive |
| B-21 | 0 | None | 0.01 | 2.1 | Inventive |
| B-22 | 0 | None | 0.01 | 2.1 | Inventive |

TABLE 4
Evaluation result of each polishing composition

| | | Tungsten | | |
|---|---|---|---|---|
| Polishing | Polishing | etching | The number of | |
| composition | speed | amount | defects | |
| No. | [Å/min] | [Å] | [Number] | |
| B-1 | 152 | 13.8 | 782 | Comparative |
| | | | | Example |
| B-2 | 161 | 11.8 | 821 | Comparative |
| | | | | Example |
| B-3 | 111 | 14.3 | 201 | Comparative |
| | | | | Example |
| B-4 | 103 | 11.8 | 234 | Comparative |
| | | | | Example |
| B-5 | 108 | 12.9 | 231 | Comparative |
| | | | | Example |
| B-6 | 114 | 11.2 | 201 | Comparative |
| | | | | Example |
| B-7 | 121 | 10.9 | 213 | Comparative |
| | | | | Example |
| B-8 | 144 | 12.5 | 276 | Comparative |
| | | | | Example |
| B-9 | 132 | 13.1 | 298 | Comparative |
| | | | | Example |
| B-10 | 114 | 12.5 | 301 | Comparative |
| | | | | Example |
| B-11 | 109 | 12.1 | 392 | Comparative |
| | | | | Example |
| B-12 | 118 | 13.8 | 458 | Comparative |
| | | | | Example |
| B-13 | 121 | 13.5 | 281 | Comparative |
| | | | | Example |
| B-14 | 150 | 4.1 | 78 | Inventive |
| B-15 | 148 | 3.9 | 101 | Inventive |
| B-16 | 142 | 4.0 | 78 | Inventive |
| B-17 | 144 | 3.3 | 32 | Inventive |
| B-18 | 141 | 2.1 | 33 | Inventive |
| B-19 | 140 | 3.0 | 42 | Inventive |
| B-20 | 144 | 3.7 | 172 | Inventive |
| B-21 | 141 | 3.8 | 178 | Inventive |
| B-22 | 140 | 3.1 | 184 | Inventive |

It was confirmed as shown from in Tables 3 and 4 that the polishing compositions B-14 to B-22 according to the present invention contain the sulfonic acid compound or the salt thereof which contains a nitrogen atom and has a molecular weight of less than 1,000, and the remarkable tungsten dissolution inhibiting effect is shown while the polishing speed is maintained or the number of defects was significantly reduced by performing the polishing using these compositions. On the other hand, it was confirmed that the polishing compositions B-1 to B-13 not containing the sulfonic acid compound or the salt thereof which contains the nitrogen atom and has the molecular weight of less than 1,000, which deviate from the scope of the present invention, reduce the tungsten dissolution inhibiting effect, do not reduce the number of defects, reduce the polishing speed or increase the number of defects depending on the used compound in some cases, and cannot obtain a sufficient effect.

This application is based on Japanese Patent Application No. 2018-178726 filed on Sep. 25, 2018, the disclosure of which is incorporated herein by reference in its entirety.

What is claimed is:

1. A tungsten dissolution inhibitor, comprising a sulfonic acid compound or a salt thereof which contains a nitrogen atom and has a molecular weight of less than 1,000.

2. The tungsten dissolution inhibitor according to claim 1, wherein the sulfonic acid compound or the salt thereof is represented by the following formula (1): 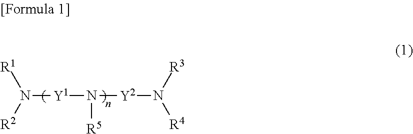
in the formula (1), Y¹ and Y² each independently represent a linear or branched alkylene group having 1 or more and 5 or less carbon atoms,
n is an integer of 0 or more and 4 or less,
R¹ to R⁵ each independently represent a hydrogen atom, a sulfonic acid (salt) group or a substituted or unsubstituted linear or branched alkyl group having 1 or more and 5 or less carbon atoms, and
in this case, at least one of R¹ to R⁵ is a sulfonic acid (salt) group or an alkyl group substituted with the sulfonic acid (salt) group.

3. The tungsten dissolution inhibitor according to claim 2, wherein in the above formula (1), at least four of R¹ to R⁵ is a sulfonic acid (salt) group or an alkyl group substituted with the sulfonic acid (salt) group.

4. The tungsten dissolution inhibitor according to claim 1, further comprising a dispersing medium.

5. A polishing composition which is the tungsten dissolution inhibitor according to claim 4, further comprising an abrasive grain, and is used for polishing an object to be polished having a tungsten-containing layer.

6. The polishing composition according to claim 5, further comprising a polymer compound having an anionic functional group or a group of a salt thereof and having a weight average molecular weight of 1,000 or more.

7. The polishing composition according to claim 5, wherein the dispersing medium contains water and a pH is less than 7.

8. A method of producing a polishing composition, comprising mixing a sulfonic acid compound or a salt thereof containing a nitrogen atom and having a molecular weight of less than 1,000 with a dispersing medium and an abrasive grain, wherein the polishing composition is used for polishing an object to be polished having a tungsten-containing layer.

9. A polishing method, comprising polishing an object to be polished having a tungsten-containing layer using the polishing composition according to claim 5.

10. A method of manufacturing a semiconductor substrate, comprising polishing an object to be polished having a tungsten-containing layer by the polishing method according to claim 9.

11. A composition for surface treatment which is the tungsten dissolution inhibitor according to claim 4, wherein the composition for surface treatment is used for treating a surface of a polished object to be polished having a tungsten-containing layer.

12. The composition for surface treatment according to claim 11, wherein the composition for surface treatment is substantially free of an abrasive grain.

13. The composition for surface treatment according to claim 11, further comprising a polymer compound having an anionic functional group or a group of a salt thereof and having a weight average molecular weight of 1,000 or more.

14. The composition for surface treatment according to claim 11, wherein the composition for surface treatment is substantially free of an oxidizing agent.

15. The composition for surface treatment according to claim 11, wherein the dispersing medium contains water and a pH is less than 7.

16. A method of producing a composition for surface treatment, comprising mixing a sulfonic acid compound or a salt thereof containing a nitrogen atom and having a molecular weight of less than 1,000 with a dispersing medium, wherein the composition for surface treatment is used for treating a surface of a polished object to be polished having a tungsten-containing layer.

17. A surface treatment method, comprising performing surface treatment on a polished object to be polished having a tungsten-containing layer using the composition for surface treatment according to claim 11.

18. The surface treatment method according to claim 17, wherein the surface treatment is rinse polishing treatment or cleaning treatment.

19. A method of manufacturing a semiconductor substrate, comprising performing surface treatment on a polished object to be polished having a tungsten-containing layer by the surface treatment method according to claim 17.
